(19) United States
(12) Patent Application Publication
(10) Pub. No.: US 2020/0181007 A1
(43) Pub. Date: Jun. 11, 2020

(54) Spiral Grain Coatings for Glass Structures in Electronic Devices

(71) Applicant: Apple Inc., Cupertino, CA (US)

(72) Inventors: Tyler A. Marshall, Sunnyvale, CA (US); Martin Melcher, Mountain View, CA (US); Matthew S. Rogers, San Jose, CA (US)

(21) Appl. No.: 16/457,389

(22) Filed: Jun. 28, 2019

Related U.S. Application Data
(60) Provisional application No. 62/776,982, filed on Dec. 7, 2018.

(51) Int. Cl. C03C 17/22; H05K 5/00; H05K 5/03; G02B 1/113; G02B 1/14; C01B 21/06; C09D 1/00; C09D 5/00

(52) U.S. Cl. CPC C03C 17/225; H05K 5/0017; H05K 5/03; G02B 1/113; G02B 1/14; C03C 2218/154; C01B 21/0602; C09D 1/00; C09D 5/006; C03C 2217/732; C03C 2217/78; H05K 5/0086

(57) ABSTRACT

An electronic device may include electrical components mounted within a housing. The device may have a display on a front face of the device that is covered with a glass structure and may have a glass structure that forms part of the housing on a rear face of the device. The housing may also have a sidewall formed from glass, metal, or other materials. The glass structures of the electronic device may have a surface that is covered with an antiscratch layer, an antireflection layer, or other coating. A spiral grain polycrystalline material may form a coating on the surface of the glass structures to help avoid fracturing of the glass structures when the electronic device is dropped or otherwise subjected to stress.

This application claims the benefit of provisional patent application No. 62/776,982, filed Dec. 7, 2018, which is hereby incorporated by reference herein in its entirety.

### BACKGROUND

This relates generally to coatings, and, more particularly, to coatings for glass structures in electronic devices.

Electronic devices such as cellular telephones, computers, watches, and other devices may contain glass structures. For example, electronic devices may have displays in which an array of pixels is covered with a protective layer of glass. In some devices, a rear housing wall may be formed from a layer of glass.

It may be desirable to coat glass structures with coatings such as antiscratch coatings and antireflection coatings. However, the presence of thin-film coatings on a glass surface has the potential to create stress concentrations that make the glass structure susceptible to breakage. If care is not taken, glass structures may be susceptible to cracking when subjected to elevated stress during an unintended drop event.

### SUMMARY

An electronic device may have a housing. The housing may have a transparent portion such as a glass layer that forms a display cover layer on a front face of the device. The display cover layer may cover and protect an array of pixels in a display layer such as an organic light-emitting diode display layer. The housing may also have glass structures that form housing sidewalls and/or a housing wall on a rear face of the device.

Thin-film coating layers may be deposited on the housing using physical vapor deposition or other deposition techniques. The coating layers may be transparent coatings that form antireflection layers, antiscratch layers, opaque layers that may be patterned to form logos, text, or other visual elements, and/or other coating layers.

To prevent damage to a glass structure in the event that the electronic device is dropped or otherwise subjected to stress, the coating layers on the glass structures of the electronic device may formed from polycrystalline materials in which grains have been grown in an interlaced spiral configuration.

### BRIEF DESCRIPTION OF THE DRAWINGS

FIG. 1 is a perspective view of an illustrative electronic device of the type that may include a glass structure with a coating in accordance with an embodiment.

FIG. 2 is a cross-sectional side view of an illustrative electronic device with a coating in accordance with an embodiment.

FIG. 3 is a cross-sectional side view of an illustrative glass structure such as a housing structure that has a coating in accordance with an embodiment.

FIG. 4 is a cross-sectional side view of an illustrative system for forming coatings with spiral grain structures in accordance with an embodiment.

FIG. 5 is a top view of illustrative interlaced spiral grains in a coating in accordance with an embodiment.

FIG. 6 is a side view of an illustrative spiral grain in a coating layer in accordance with an embodiment.

### DETAILED DESCRIPTION

Electronic devices and other items may be provided with structures that are formed from glass. For example, an electronic device may include a display on a front face of the device. The display may have an array of pixels for displaying images for a user. To protect the pixel array from damage, the display may be covered with a layer of glass that serves as a display cover layer. Other portions of electronic devices may also include glass structures. For example, a rear face and edge portions of an electronic device may be covered with a layer of glass. In this type of arrangement, the glass forms a housing surface that is pleasing to the touch. Glass structures may also be used as optical windows, buttons, and/or other structures in an electronic device.

It may be desirable to form a coating layer on a glass structure to provide the glass structure with desired optical and/or physical attributes. As an example, it may be desired to reduce light reflections from a glass structure by providing the glass structure with an antireflection coating. An antireflection coating may be formed from a dielectric stack such as a stack of thin-film dielectric layers of alternating refractive index values. One or more thin-film layers may also be deposited on a glass structure to form an antiscratch coating. Cosmetic coating layers may also be formed (e.g., a glass structure may be covered with a blanket coating layer or a patterned coating layer in the shape of a logo, decorative trim, text, or other shape). Cosmetic coating layers may be opaque and/or may have other appearances. In some configurations, thin-film coatings may serve multiple functions. For example, an antireflection layer may incorporate hard materials that allow the antireflection layer to serve as an antiscratch layer.

In general, thin-film coatings for an electronic device may include dielectric materials (e.g., polymer, inorganic dielectrics such as oxides, carbides, nitrides, etc.), metals, and/or semiconductors and may be formed on any suitable substrate (e.g., substrates such as electronic device structures formed from glass, metal, crystalline material such as sapphire, polymer, etc.). Illustrative arrangements in which thin-film coatings for an electronic device are formed on an outer surface of a glass housing structure may sometimes be described herein as an example.

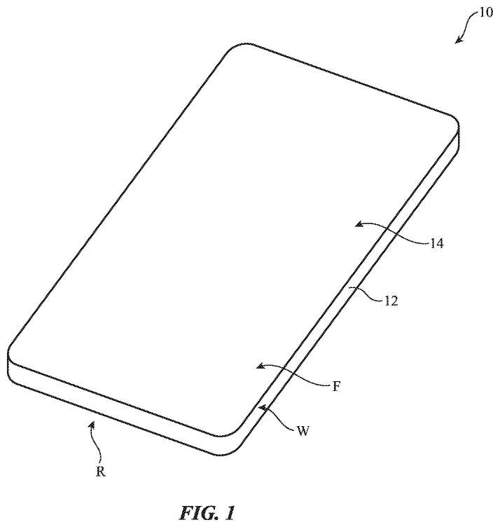

An illustrative electronic device of the type that may include glass structures is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wristwatch device (e.g., a wristwatch with a wrist strap), a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, equipment that implements the functionality of two or more of these devices, or other electronic equipment. In the illustrative configuration of FIG. 1, device 10 is a portable device such as a cellular telephone, media player, tablet computer, wrist device, or other portable computing device. Other configurations may be used for device 10 if desired. The example of FIG. 1 is merely illustrative.

In the example of FIG. 1, device 10 includes a display such as display 14. Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may include an array of pixels formed from liquid crystal display (LCD) components, an array of electrophoretic pixels, an array of plasma pixels, an array of organic light-emitting diode pixels or other light-emitting diodes such as light-emitting diodes formed from crystalline semiconductor dies, an array of electrowetting pixels, or pixels based on other display technologies. For example, display 14 may be an organic light-emitting diode display or a liquid crystal display.

Device 10 may have a housing such as housing 12. Housing 12, which may sometimes be referred to as an enclosure or case, may be formed of plastic, glass, ceramics, fiber composites, metal (e.g., stainless steel, aluminum, titanium, gold, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.).

Housing 12 may include one or more transparent portions. For example, a portion of housing 12 may be formed from a layer of transparent material such as glass that serves as a display cover layer. The display cover layer may cover and protect the pixels of display 14. Display 14 may be formed on front face F of device 10 or other portion of device 10.

Other structures in device 10 may also be formed from glass. For example, portions of housing 12 on rear face R and/or portions of housing 12 forming a sidewall W that extends between the portion of housing 12 on front face F and the portion of housing 12 on rear face R may be formed from glass. Glass structures in device 10 such as glass portions of housing 12 may include planar glass layers and glass members with non-planar shapes such as shapes with curved cross-sectional profiles, glass layers with bends along the peripheral edges of device 10, glass window structures for cameras and other optical components, and/or other glass members with planar and/or curved shapes.

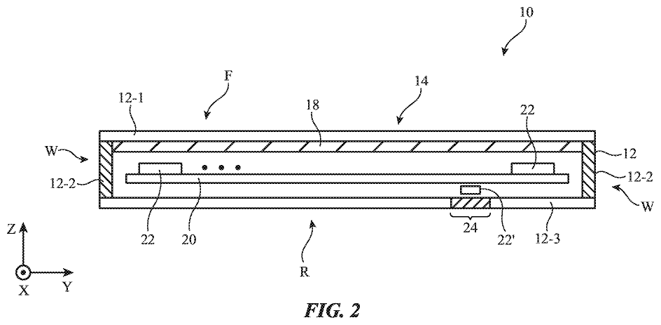

FIG. 2 is a cross-sectional side view of an illustrative device such as device 10 of FIG. 1 that contains glass structures. As shown in FIG. 2, housing 12 of device 10 may surround an interior region that includes components such as components 22. Components 22 may include integrated circuits, discrete components, control circuitry, wired and/or wireless communications circuitry (e.g., cellular telephone transceiver circuitry, wireless local area network transceiver circuitry, antennas, etc.), sensors, light-emitting diodes, image sensors, photodetectors, and/or other optical components, and/or other input-output devices. Components 22 may be electrically coupled together by mounting components 22 to one or more substrates such as printed circuit 20.

In the illustrative configuration for device 10 of FIG. 2, housing 12 of device 10 has portions such as portion 12-1 on front face F of device 10, portion 12-2 that forms sidewall W for device 10, and portion 12-3 that forms a rear housing wall on rear face R of device 10. Portions 12-1, 12-2, and 12-3 may include structures formed from glass, polymer, metal, ceramic, sapphire or other crystalline materials, fabric, wood or other natural materials, and/or other materials. Adhesive and/or other joining structures may be used to join multiple structures together to form one or more of portions 12-1, 12-2, and/or 12-3.

Display 14 may include display layer 18 (e.g., a rigid or flexible display layer that forms an array of pixels configured to present images for a user on front face F of device 10). Display layer 18 may be overlapped by a transparent portion of housing 12 such as housing portion 12-1. Housing portion 12-1 may be, for example, a glass layer that serves as a display cover layer that protects the pixel array in display layer 18.

Housing portion 12-3 may form a rear housing wall for device 10. In one illustrative arrangement, housing portion 12-3 may be formed from a layer of glass. The inner surface of the layer of glass may be coated with one or more layers of material (e.g., colored ink, thin-film inorganic coating layers, metal layers, etc.) to make housing portion 12-3 opaque and thereby hide internal components from view or housing portion 12-3 may form a display cover layer for a rear-facing display. Portion 12-2 may extend between housing portion 12-3 on rear face R of device 10 and housing portion 12-1 on front face F of device 10 and may form sidewall W. Sidewall W may be formed from a metal band or other structure that is separate from portions 12-1 and 12-3 and/or some or all of sidewall W may be an integral portion of portion 12-1 and/or 12-3. If desired, sidewall W or a portion of sidewall W may be formed from a transparent material such as glass.

If desired, housing portion 12-3 may be formed from an opaque material (e.g., polymer, metal, etc.) and may contain one or more window openings filled with transparent material such as glass window material. As shown in FIG. 2, for example, portion 24 of rear housing portion 12-3 may be formed from a transparent material such as glass and the remainder of housing portion 12-3 may be formed from glass and/or opaque polymer, metal, or other non-transparent material (e.g., a glass disk or other structure may be mounted in a circular window opening in a housing wall formed from metal, polymer, glass, etc.).

If desired, optical components such as light-emitting and/or light-detecting components may operate through one or more transparent portions of housing 12. As an example, a transparent window formed from glass or other material in portion 24 of housing portion 12-3 may be aligned with one or more optical components such as optical component 22′. Component 22′ may be a light-emitting diode for a camera flash or other light-emitting device and/or may be a light detecting component such as an ambient light sensor, proximity sensor, or digital image sensor (as examples).

Glass structures in device 10 such as one or more portions of housing 12 (e.g., one or more parts of portions 12-1, 12-2, and/or 12-3) may be provided with coatings. The coatings may serve as antireflection layers, antiscratch layers, cosmetic coatings (e.g., opaque layers to hide internal components from view and/or patterned coatings forming logos, text, trim, etc.), and/or other coatings.

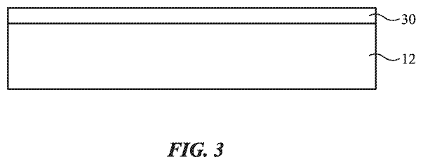

A coating with a vertically aligned grain structure will tend to fracture vertically. This can cause a crack to propagate from the coating into an underlying glass structure, thereby damaging the glass structure. To avoid undesirably weakening glass portions of housing 12, glass structures in device 10 may be coated with materials that have spiral grains. As shown in FIG. 3, a glass structure such as a glass member in housing 12 may, for example, be coated with a coating 30. Coating 30 may be a polycrystalline layer with a spiral grain structure. In the spiral grain structure, grains of material have an interlaced spiral configuration that deflects fractures away from the glass structure rather than propagating into the glass structure. This helps prevents fractures in the coating from propagating into housing 12 and damaging housing 12. The use of spiral grain coatings on glass housing structures in device 10 may therefore help make device 10 more robust and less susceptible to damage during unexpected drop events and other events in which elevated stress is imposed on device 10.

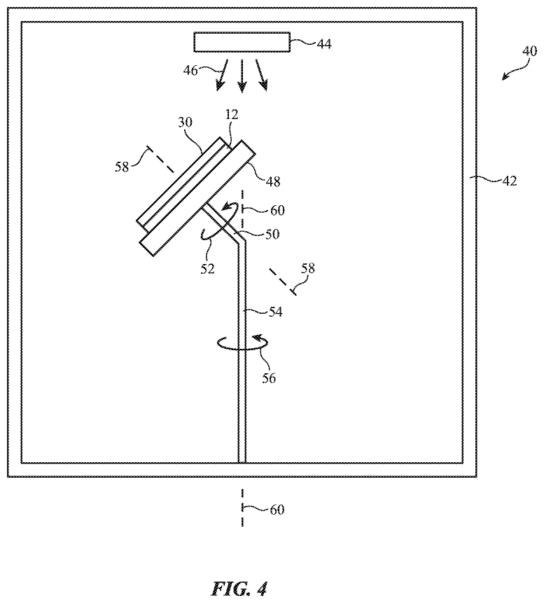

FIG. 4 is a cross-sectional side view of an illustrative deposition system for depositing spiral grain coatings on glass structures for device 10. As shown in FIG. 4, coating deposition system 40 may have a vacuum chamber such as chamber 42. During operation, a coating material source such as source 44 in a vacuum in the interior of chamber 42 may be used to deposit material 46 to form spiral-grain coating 30 on a substrate such as a portion of housing 12. Source 44 may be, for example, a set of one or more sputtering targets and system 40 may be a physical vapor deposition system (e.g., a sputtering tool).

As shown in FIG. 4, the substrate (housing 12) onto which coating 30 is deposited during physical vapor deposition operations may be mounted on a rotating support structure such as rotating support 48 (e.g., a vacuum chuck). Support 48 may be supported by rotating arm 50. Rotating arm 50 may rotate in direction 52 about axis 58. This rotates support 48 and the substrate (housing 12) that is coupled to support 48 and thereby creates spiral grain growth in coating 30 as material 46 is deposited. The process conditions within chamber 42 may be adjusted to promote desired grain growth. For example, the pressure in chamber 42 can be sufficiently high to promote scattering of target atoms and thereby ensure that coating 30 has a desired porosity. As another example, the temperature of substrate 12 can be adjusted (e.g., by adjusting the temperature of support 48) so that the atoms of material being deposited from source 44 will be sufficiently energetic to promote growth of crystalline grains in coating 30. Support 50 may be supported by support 54. Support 54 may be rotated about vertical axis 60 during deposition operations to promote uniformity in coating 30.

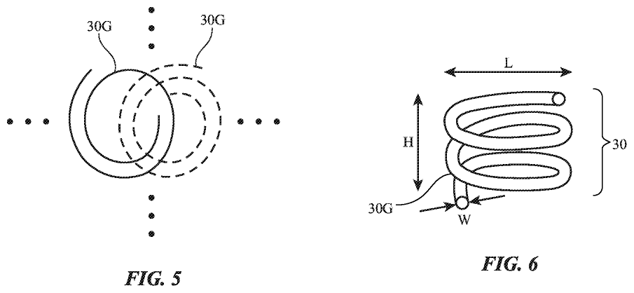

Using an arrangement of the type shown in FIG. 4, interlaced spiral grains may be formed in coating 30, as illustrated by interlaced spiral grains 30G in the top view of coating 30 of FIG. 5. Grains 30G, which may sometimes be referred to as crystallites or microscopic crystals, may have any suitable configuration. As shown in the side view of FIG. 6, for example, coating 30 may be characterized by spiral grains 30G with a height H and lateral dimension L. Height H, which may be equal to some or all of the thickness of layer 30 may have a value of at least 50 angstroms, at least 100 angstroms, at least 500 angstroms, at least 0.1 microns, at least 0.3 microns, at least 1 micron, at least 2 microns, less than 1.5 microns, less than 0.7 microns, less than 0.4 microns, less than 0.2 microns, less than 0.5 microns, less than 0.2 microns, less than 700 angstroms, less than 400 angstroms, or other suitable height. The thickness of layer 30 may be at least 50 angstroms, at least 100 angstroms, at least 500 angstroms, at least 0.1 microns, at least 0.3 microns, at least 1 micron, at least 2 microns, less than 1.5 microns, less than 0.7 microns, less than 0.4 microns, less than 0.2 microns, less than 0.5 microns, less than 0.2 microns, less than 700 angstroms, less than 400 angstroms, or other suitable thickness. Thinner coatings such as coatings of at least 50 angstroms or at least 100 angstroms in thickness may be used for antireflection coatings and thicker coatings such as coatings of 0.5 microns or 1 micron in thickness may be used when forming an opaque layer. There may be any suitable number of turns N in the spiral of each grain 30G. For example, the value of N may be at least 2, at least 3, at least 5, at least 7, at least 9, fewer than 12, fewer than 10, fewer than 8, fewer than 6, fewer than 4, fewer than 2, 2-10, 3-10, or other suitable value. The lateral dimension L of spiral grain 30G may be at least 0.1 microns, at least 0.5 microns, less than 0.2 microns, less than 0.05 microns, less than 0.01 microns, or other suitable width. The width W (diameter) of spiral grain 30G may be may be at least 0.01 microns, at least 0.1 microns, at least 0.5 microns, less than 0.2 microns, less than 0.05 microns, less than 0.01 microns, or other suitable size. To enhance the ability of grain 30G to grow in a spiral shape, grain 30G may be elongated (e.g., height-to-width ratio H/W, which may sometimes be referred to as a length-to-width ratio or length-to-diameter ratio, may be at least 2, at least 3, at least 4, at least 7, at least 10, less than 1000, less than 500, less than 100, less than 50, or other suitable value).

In some configurations, coating 30 may be formed on the outer surface of housing 12 (e.g., the outer surface of one or more glass structures in housing 12, etc.). Particularly when formed in this location, coating 30 may be formed from a hard material such as a nitride (e.g., carbon nitride, silicon nitride, a metal nitride such as titanium nitride or titanium aluminum nitride, etc.), a carbide, a carbon nitride, an oxide (e.g., a metal oxide, silicon oxide, etc.), an oxynitride, etc. Dielectric coatings may form thin-film interference filters. For example, coating 30 may include multiple sublayers (e.g., alternating higher and lower refractive index layers) and may be used to form a thin-film interference filter mirror, a thin-film interference filter with a desired passband and/or stop band, an infrared-light-blocking thin-film interference filter, a thin-film antireflection layer coating, and/or other suitable thin-film interference filter. Coating 30 may also be used to prevent excess wear on glass structures (e.g., coating 30 may form an antiscratch layer for a glass portion of housing 12), an antismudge layer, and/or an antireflection layer.

The foregoing is merely illustrative and various modifications can be made to the described embodiments. The foregoing embodiments may be implemented individually or in any combination.

What is claimed is:

1. An electronic device, comprising:
a housing comprising a glass structure;
electrical components in an interior of the housing; and
a spiral grain polycrystalline coating on the glass structure.

2. The electronic device defined in claim 1, wherein the electronic device has opposing front and rear faces, wherein the electronic device comprises a display, wherein a portion of the housing on the front face forms a display cover layer that overlaps the display, and wherein the glass structure forms a glass rear housing wall on the rear face.

3. The electronic device defined in claim 2 wherein the glass rear housing wall has an interior surface facing the interior and has an opposing exterior surface and wherein the spiral grain polycrystalline coating is on the exterior surface.

4. The electronic device defined in claim 3 wherein the spiral grain polycrystalline coating comprises a nitride.

5. The electronic device defined in claim 4 wherein the nitride comprises a metal nitride.

6. The electronic device defined in claim 5 wherein the metal nitride comprises titanium aluminum nitride.

7. The electronic device defined in claim 3 wherein the spiral grain polycrystalline coating comprises interlaced spiral grains that each have 2-10 spiral turns.

8. The electronic device defined in claim 3 wherein the spiral grain polycrystalline coating comprises spiral grains having widths and having lengths that are at least 3 times larger than the widths.

9. The electronic device defined in claim 1 further comprising a display, wherein the glass structure has an exterior surface and covers the display and wherein the spiral grain polycrystalline coating is on the exterior surface.

10. The electronic device defined in claim 1 wherein the spiral grain polycrystalline coating is configured to form an antireflection layer.

11. The electronic device defined in claim 1 wherein the spiral grain polycrystalline coating is configured to form an antiscratch layer.

12. The electronic device defined in claim 1 further comprising a display, wherein the glass structure has an exterior surface and covers the display and wherein the spiral grain polycrystalline coating forms an antireflection layer on the exterior surface.

13. The electronic device defined in claim 1 wherein the spiral grain polycrystalline coating comprises interlaced spiral grains formed from a nitride.

14. An apparatus, comprising:
a glass member; and
a spiral grain polycrystalline coating on a surface of the glass member.

15. The apparatus defined in claim 14 wherein the glass member comprises a display cover layer.

16. The apparatus defined in claim 15 further comprising a pixel array overlapped by the display cover layer, wherein the spiral grain polycrystalline coating comprises an antireflection layer.

17. The apparatus defined in claim 14 wherein the glass member comprises an electronic device housing wall and wherein the spiral grain polycrystalline coating comprises an antiscratch layer on the electronic device housing wall.

18. A portable electronic device having opposing front and rear faces, comprising:
a display on the front face that has a pixel array configured to display an image;
glass housing structures having a first glass portion that overlaps the display and having a second glass portion on the rear face; and
a spiral grain polycrystalline coating on a surface of the glass housing structures.

19. The portable electronic device defined in claim 18 wherein the spiral grain polycrystalline coating is formed on the first glass portion, is configured to from an antireflection coating, and has a thickness of at least 50 Angstroms.

20. The portable electronic device defined in claim 18 wherein the spiral grain polycrystalline coating is formed on the second glass portion, is configured to from an antiscratch coating, and has a thickness of at least 1000 Angstroms.
